(19) United States
(12) Patent Application Publication
(10) Pub. No.: US 2025/0117562 A1
(43) Pub. Date: Apr. 10, 2025

(54) SYSTEM AND METHOD FOR GLOBAL FLOORPLANNING VIA SEMIDEFINITE PROGRAMMING

(71) Applicant: CARNEGIE MELLON UNIVERSITY, Pittsburgh, PA (US)

(72) Inventors: Wei Li, Pittsburgh, PA (US); Ronald Blanton, Pittsburgh, PA (US); Jose M. F. Moura, Pittsburgh, PA (US)

(73) Assignee: CARNEGIE MELLON UNIVERSITY, Pittsburgh, PA (US)

(21) Appl. No.: 18/910,938

(22) Filed: Oct. 9, 2024

Related U.S. Application Data
(60) Provisional application No. 63/543,393, filed on Oct. 10, 2023.

(51) Int. Cl. G06F 30/392; G06F 30/398

(52) U.S. Cl. CPC G06F 30/392; G06F 30/398

(57) ABSTRACT

Disclosed herein is a framework for modeling the global floorplanning problem as a semi-definite programming (SDP) problem with an inner product between the target matrix and a direction matrix replacing the rank constraint. The framework is global optimal if an appropriate direction matrix is chosen, which is calculated using a convex iteration algorithm that decomposes the problem into two SDP sub-problems.

### RELATED APPLICATIONS

This application claims the benefit of U.S. Provisional Patent Application No. 63/543,393, filed Oct. 10, 2023, the contents of which are incorporated herein in their entirety.

### FIELD OF THE INVENTION

This invention is related to the field of VLSI design and, specifically to the problem of determining the physical locations and shapes of modules present in a VLSI design.

### BACKGROUND

A major task in chip design involves identifying the locations and shapes of each major design block/module in the footprint of the chip. This is commonly known as “floorplanning”. The first step of this task is known as global floorplanning and involves identifying a location for each module that minimizes wirelength and leaves sufficient area for each module. Existing global floorplanning methods either have a non-convex problem formulation or have trivial global solutions with no guarantee on the quality of the result.

As the first stage of VLSI physical design, the quality of floorplanning is critical for the overall quality of the final design. However, floorplanning is a NP-hard problem. It is not easy to find high-quality locations and shapes at the same time. Most existing methods divide the problem into two steps: global floorplanning (i.e., initial floorplanning) and legalization.

Global floorplanning determines module locations that minimizes the wirelength and leaves enough space for each module. The legalization step gives modules concrete shapes. Wirelength is highly related to the module locations, therefore, a good global floorplan is critical for the final floorplanning quality.

In the real world, floorplanning is usually done by highly experienced experts. The problem size is reduced to a manageable level, usually less than 100 IP-cores/block. However, floorplanning is still open to better solutions. One problem with performing global floorplanning manually is that the expert may not have enough time to explore alternative floorplans. Time pressure and short physical design cycle force finishing the floorplanning in just a few days. Providing the expert with a high-quality global floorplan as a starting point will significantly accelerate the design cycle.

Existing global floorplanning methods can be roughly divided into two categories: packing-based methods and analytical-based methods. Packing-based methods translate the global floorplanning problem into a packing problem. The target (e.g., locations on a 2D plane) is represented by a delicately designed representation such as B*-tree, sequence-pair and corner sequence.

However, many “complete” representations have difficulty to dealing with natural requirements, such as the Pre-Placed Module (PPM) constraint. Moreover, working with a floorplan representation leads to inevitable accuracy loss and evaluation overhead: For example, the wirelength is calculated in a 2D plane, instead of the designed representation. Analytical-based methods minimize the wirelength by optimizing an objective function, but most existing global floorplanning methods model the floorplanning as a non-convex problem, requiring non-linear optimization methods which get trapped in a local optimum. Also, many lead to a trivial global optimal solution, for example, where all modules are placed in the same location. Therefore, it would be desirable to have a method that addresses these problems.

### SUMMARY

Disclosed herein is a framework for modeling the global floorplanning problem as a semi-definite programming (SDP) problem with rank constraint, wherein the rank constraint is replaced with an inner product between the target matrix and a direction matrix, which is shown to be global optimal if an appropriate direction matrix is chosen. To calculate the direction matrix, a convex iteration algorithm that decomposes the problem into two SDP sub-problems is used.

Furthermore, a series of techniques is disclosed that enhance the flexibility, accuracy, and efficiency of the algorithm. The disclosed method reduces the average wirelength by at least 3.02%, to 20.01% on different benchmarks and outline aspect ratios.

FIG. 1 is a schematic diagram of the process. The floorplanning framework disclosed herein takes as input constraints (e.g., area, boundaries, connectivity, etc.) and outputs a global floorplan.

### Definitions

As used herein, the term “module” should be interpreted to mean a functional portion of a VLSI design composed of, for example, gates and other circuitry, assumed to be arranged in a square or rectangular shape.

### BRIEF DESCRIPTION OF THE DRAWINGS

By way of example, a specific exemplary embodiment of the disclosed system and method will now be described, with reference to the accompanying drawings, in which:

FIG. 1 is a high level schematic of the floorplanning framework.

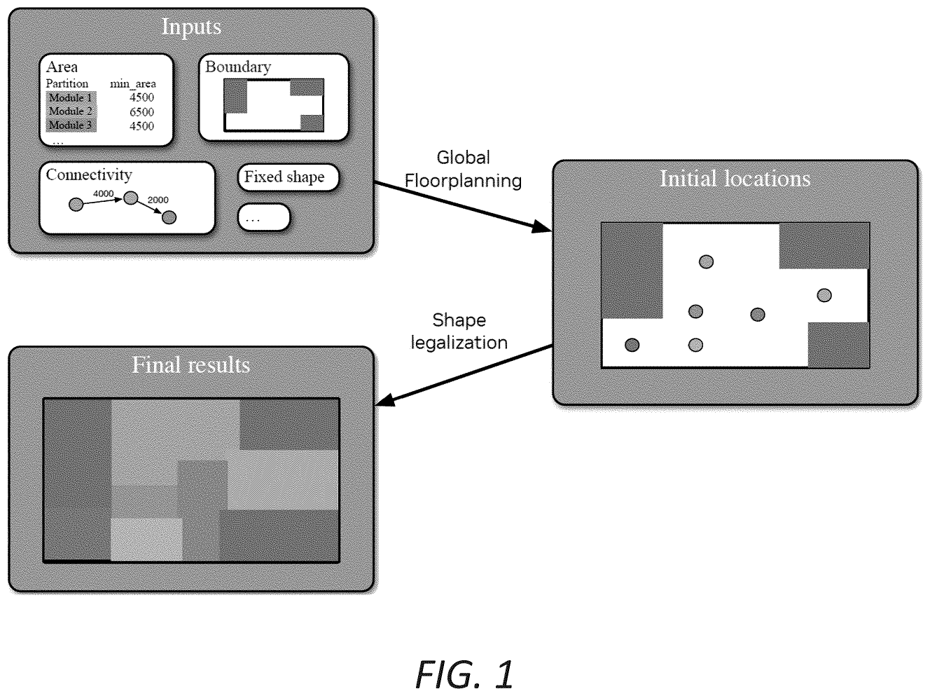

FIG. 2 is an illustration showing that the minimal values are expected to occur when the circles are tangent.

FIG. 3A is an illustration of the adaptive distance constraint. FIG. 3B shows the adaptive distance with multiple neighbors

FIG. 4 is a pseudocode version of the method.

FIG. 5 is a diagram showing the workflow of the pseudocode shown in FIG. 4.

FIG. 6 is a diagram showing the final outcome of the method.

### DETAILED DESCRIPTION

The global floorplanning problem can be formally defined as follows. The input of the global floorplanning problem is a set of n modules {p₀ . . . pₙ₋₁}, wherein each module is associated with a minimal area constraint sᵢ. That is, the module is expected to be assigned at least sᵢ area space in the final floorplan. A weighted directed connectivity graph [symbol] ={ [symbol] , ε}, represented by its adjacency matrix A, where A_{i,j} is the number of connections between modules pᵢ and pⱼ.

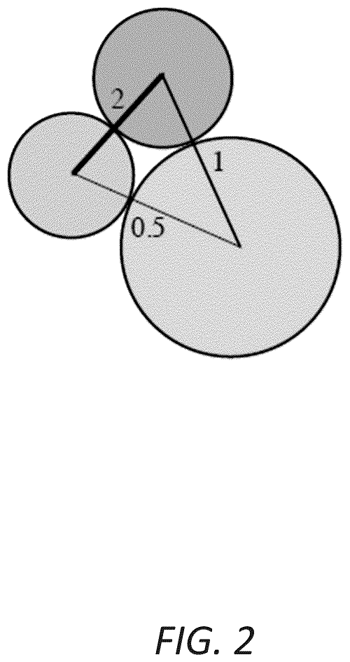

Different from a final floorplan that requires specification of module shapes, the global floorplanning problem only focuses on the locations of the modules. A “rough” position of each module is determined, such that wirelength is minimized (wirelength objective) and each module has enough area to be placed in the next step of the process (i.e., area constraint). FIG. 2 illustrates an example showing that the minimum wirelength distance is expected to occur when the circles are tangent.

Let xᵢ∈ [symbol] ^{m} be the center coordinate of module pᵢ. (Note that the invention is explained in the context of a 2D (i.e., m=2) implementation, but, as may be realized, the invention can be applied in any number of dimensions). Collect the center coordinates as the columns of a matrix X, (i.e., X=[x₀ . . . xₙ₋₁]^{T}∈ [symbol] ^{m×n}), where n is the number of modules. Formally, the objective is:

$${min}_{X} {\sum }_{i = 0}^{n} {\sum }_{j = 0}^{n} {A}_{ij} \cdot {‖ {x}_{i} - {x}_{j} ‖}_{1} \qquad ( 1 )$$

s.t. each module has enough space to be placed where Aᵢⱼ is the entry of the adjacency matrix A.

The problem can be reformulated as a “nearly-convex” optimization problem and solved by an SDP-based convex iteration. In global floorplanning, the shapes of modules are unknown. In the 2D implementation, each module p, is modeled as a circle whose center is xᵢ∈ [symbol] ² with radius rᵢ=\sqrt{sᵢ/4}, where sᵢ is the minimum area constraint of module pᵢ. Due to the absence of shapes, at this stage, the only concern is minimizing the wirelength. At the same time, the area constraint is expected to be satisfied as much as possible, that is, each module should be left with enough area for the final floorplan. Formally, the wirelength among modules is estimated by:

$$〈 A , D 〉 \qquad ( 2 )$$

where [symbol] is an inner product and A is the adjacency matrix of the connectivity graph. D is the Euclidean distance matrix, and the entry Dᵢⱼ is the Euclidean distance square between pᵢ and pⱼ, that is, Dᵢⱼ=∥xᵢ−xⱼ∥².

The Gram matrix is defined as G=X^{T}X∈ [symbol] ₊ⁿ, where [symbol] ₊ⁿ represents the positive semi-definite matrix. Because Dᵢⱼ=Gᵢᵢ+Gⱼⱼ−Gᵢⱼ−Gⱼᵢ, objective can be rewritten as:

$$〈 B , G 〉 \qquad ( 3 )$$

where B∈ [symbol] ^{n×n} is defined by:

$${B}_{i j} = \{ \begin{matrix}{\sum }_{k = 0}^{n - 1} {A}_{ik} + {\sum }_{k = 0}^{n - 1} {A}_{kj} & when i = j \\ - 2 {A}_{ij} & when i \neq j\end{matrix}$$

Note that B is a constant known matrix as A is given.

Further, the target matrix Z is defined as:

$$Z = [ \begin{matrix}I & X \\ {X}^{T} & G\end{matrix} ] ∈ {𝕊}_{+}^{2 + n} \qquad ( 4 )$$

Using Z, the constraint G=X^{T}X is relaxed to G [symbol] X^{T}X, which is exactly Z [symbol] 0 by Schur's complement. Given all definitions described, the objective and constraints can be formulated in matrix form as:

$${min}_{Z} 〈 B , G 〉 \qquad ( 5 )$$

$$s . t . {D}_{ij} \geq {( {r}_{i} + {r}_{j} )}^{2} {∀}_{i , j} ∈ \{ 0 , … , n - 1 \} \qquad ( 6 )$$

$$Z ≽ 0 rank ( Z ) = m \qquad ( 7 )$$

Eq. (6) guarantees that the Euclidean distance between two circles is larger than the sum of their radius (i.e., the area constraint). Z [symbol] 0 is a relaxation of G=X^{T}X, and Eq. (7) ensures that the equation G=X^{T}X holds.

Without the rank constraint in Eq. (7), the problem is an SDP problem (Note that Dᵢⱼ=Gᵢᵢ+Gⱼⱼ−Gᵢⱼ−Gⱼᵢ is also an inner product between some constant matrix C and the Gram matrix G). However, the rank constraint makes the problem non-convex. The rank constraint is replaced with a direction matrix Wₒₚₜ. Formally, the main problem can be rewritten as:

$${min}_{Z} 〈 B , G 〉 + α 〈 {W}_{opt} , Z 〉 s . t . {D}_{ij} \geq {( {r}_{i} + {r}_{j} )}^{2} {∀}_{i , j} ∈ \{ 0 , … , n - 1 \} Z ≽ 0 \qquad ( 8 )$$

Here, α is a hyper-parameter controlling the rank constraint penalty. With an appropriate Wₒₚₜ (i.e., [symbol] Wₒₚₜ, Z [symbol] =0), the two problems are equivalent, which means the global optimal solution in the convexified problem is also equivalent to the global optimum in the main problem.

Note that replacing the rank constraint in this manner is only one possible embodiment and the invention is not meant to be limited to this embodiment. For example, in an alternative embodiment, the rank constraint can be replaced with a nuclear norm convex relaxation.

The intuitive explanation for Wₒₚₜ is as follows. The rank constraint rank (Z)=2 can be rewritten as:

$$trace ( Z ) - {λ}_{0} - {λ}_{1} = 0 \qquad ( 9 )$$

where λ₀ and λ₁ are the two largest eigenvalues of Z and can be calculated by

$${λ}_{0} = {max}_{‖ {u}_{0} ‖ = 1} {u}_{0}^{Y} Z {u}_{0} {λ}_{1} = {max}_{‖ {u}_{0} ‖ = 1 , {u}_{1} ⊥ {u}_{0}} {u}_{1}^{Y} Z {u}_{1} \qquad ( 10 )$$

Then, the rank constraint in Eq. (10) can be rewritten as:

$$\{ Z : {min}_{‖ {u}_{0} ‖ = 1 , ‖ {u}_{1} ‖ = 1 , {u}_{1} ⊥ {u}_{0}} 〈 I = {[ {u}_{0} , {u}_{1} ] [ {u}_{0} , {u}_{1} ]}^{T} , Z 〉 = 0 \} \qquad ( 11 )$$

Eq. (11) is equivalent to:

$$\{ Z : 〈 W , Z 〉 = 0 \} \qquad ( 12 )$$

Adding Eq. (12) back into Eq. (3) with a coefficient α, the rank constraint is re-written as a bilinear term in the objective function.

Consider an optimal solution Zₒₚₜ for the main problem. Selecting Wₒₚₜ=Uₒₚₜ*Uₒₚₜ^{T} makes the convexified problem equivalent to the main problem, where columns of Uₒₚₜ, are the normalized eigenvectors of Zₒₚₜ corresponding to the n smallest eigenvalues. However, this is infeasible because Xₒₚₜ is unknown and needs to be determined.

To obtain Wₒₚₜ and the corresponding optimal solution Zₒₚₜ, the problem is decomposed into two SDP sub-problems:

### Sub-Problem 1:

$${min}_{Z ∈ {𝕊}^{2 + n}} 〈 B , G 〉 + α 〈 {W}^{*} , Z 〉 s . t . {D}_{ij} \geq {( {r}_{i} + {r}_{j} )}^{2} {∀}_{i , j} ∈ \{ 0 , … , n - 1 \} Z ≽ 0 \qquad ( 13 )$$

### Sub-Problem 2:

$${min}_{W ∈ {𝕊}^{2 + n}} 〈 W , {Z}^{*} 〉 \qquad ( 14 )$$

$$s . t . I ≽ W ≽ 0$$

$$trace ( W ) = n$$

The two sub-problems are solved iteratively. That is, W* is the optimal solution from Eq. (14) and Z* is the optimal solution from Eq. (13), respectively. At each iteration, W is first fixed and Z is optimized. Then, the optimized Z is fixed and W is optimized. The optimization terminates when the change of either W or Z becomes trivial (i.e., is below a certain, threshold). The threshold could be fixed or could be a learned value.

At the first iteration, W* is initialized, in one embodiment, as W⁰=I, which reduces [symbol] W*, Z [symbol] in Eq. (13) to a trace heuristic for minimizing the rank using the 1-norm of the diagonal entries, whose 0-norm is the rank. The iteration is stopped when the objective values of Eqs. (13) and (14) are not improved. When the iteration converges to a point such that [symbol] W*, Z*=0 [symbol] , the rank constraint is satisfied, and the result is the global optimal solution of the convexified problem.

In reality, there are many other requirements that need to be considered, (e.g., boundary I/O pads). The following techniques are disclosed that enhance flexibility, accuracy, and efficiency of the algorithm.

### Euclidean Distance Square to Manhattan Distance

In the objective function given in Eq. (2), a Euclidean distance square matrix D is used to estimate the wirelength. The Manhattan distance may estimate the wirelength better. Sometimes, an optimal solution that minimizes Euclidean distance square does not guarantee optimal wirelength and may even be a bad solution in terms of wirelength.

To address this issue, an adaptive B matrix is used that changes during the iterations. Let Dᵢⱼ^{(t)}, MDᵢⱼ^{(t)} be the Euclidean distance square and the Manhattan distance between xᵢ and xⱼ at iteration t, respectively. At each iteration t, rather than minimizing the cost cᵢⱼ^{(t)}=AᵢⱼDᵢⱼ^{(t)} that is quantified by Euclidean distance square, an adaptive cost is minimized by:

$${c}_{ij}^{′ ( t )} = \frac{{MD}_{ij}^{( t - 1 )}}{{D}_{ij}^{( t - 1 )}} {c}_{ij}^{( t )} = \frac{{MD}_{ij}^{( t - 1 )}}{{D}_{ij}^{( t - 1 )}} {A}_{ij} {D}_{ij}^{( t )} \qquad ( 15 )$$

Because the Manhattan distance and the Euclidean distance square between two modules do not change significantly for any single iteration, the adaptive cost cᵢⱼ^{′(t)} is close to the cost quantified by real wirelength

To do this, for t>0, Aᵢⱼ^{(t)} is updated as:

$${A}_{ij}^{( t )} = \frac{{MD}_{ij}^{( t - 1 )}}{{D}_{ij}^{( t - 1 )}} {A}_{ij}$$

and B at each iteration is also updated based on A^{(t)}.

The technique can be extended to hyper-edges. Let e={pₑ⁰, . . . , pₑ^{k}} be the hyper-edge connecting k modules. Then, at each iteration, e only influences Aᵢⱼ if i and j are connected by e, and both of them are on the boundary of the bounding box of e at the last iteration.

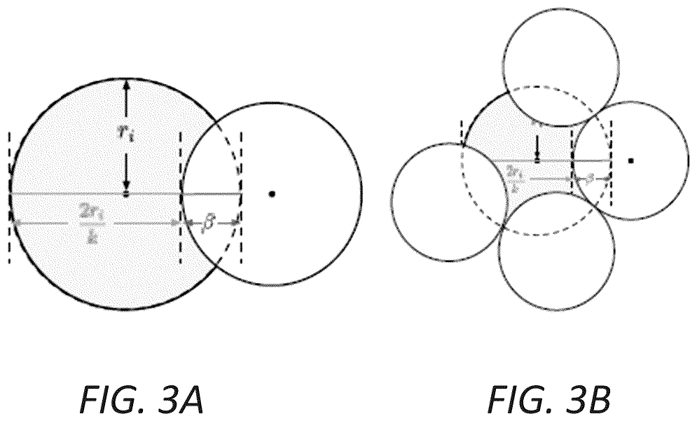

FIG. 3A illustrates an adaptive distance constraint. The shaded part is an approximation of a rectangle with height and width 2rᵢ/k. FIG. 3B illustrates multiple neighbors that cause the circle to be squashed.

### Boundary Pin and Fixed Outline

Modules may sometimes be connected to boundary pins (e.g. I/O pads). These boundary pins can be inserted into the framework without adding variables. Suppose m boundary pins, having center coordinates forming a matrix X̅∈ [symbol] ^{2×m}, Ā∈ [symbol] ^{n×m} is the matrix storing the connectivity information from modules to boundary pins. Āᵢⱼ is the number of signals passed from module pᵢ to the jₜₕ boundary pin. The objective function between pᵢ to the jₜₕ boundary pin is estimated by their Euclidean distance square: c̅ᵢⱼ=ĀᵢⱼD̅ᵢⱼ where D̅ᵢⱼ=∥xᵢ−xⱼ∥²=Gᵢᵢ−2xᵢx̅ⱼ+x̅ⱼ². Formally, minimizing c̅ᵢⱼ is equivalent to:

$${min}_{{x}_{i}} 〈 \overline{B} , Z 〉 \qquad ( 16 )$$

Where B̅ is all-zero except:

$${\overline{B}}_{2 + i , 2 + 1} = {\overline{A}}_{ij} \qquad ( 1 )$$

$${\overline{B}}_{2 + i , : 2} = - 2 {\overline{x}}_{j}^{T} \qquad ( 2 )$$

$${\overline{B}}_{: 2 , 2 + i} = - 2 {\overline{x}}_{j} \qquad ( 3 )$$

Integrating the objective expressed in Eq. (16), the wirelength between modules to boundary pins is also minimized.

Another special case is, given the outline of the chip, a simple modification is to add a lower bound and upper bound of X, which is just a part of Z

### Pre-Placement Constraint

Modules may be pre-placed, imparting a Pre-Placed Module (PPM) constraint. If a module pᵢ is fixed, then xᵢ will have a given fixed value. The framework can be easily extended to handle PPM constraints by adding equation constraints in the main problem and the first sub-problem. After adding PPM constraints, the main problem becomes:

$${min}_{z} 〈 B , G 〉 \qquad ( 17 )$$

$$s . t . {D}_{ij} \geq {( {r}_{i} + {r}_{j} )}^{2} {∀}_{i , j} ∈ \{ 0 , … , n - 1 \}$$

$${G}_{ij} = {x}_{i}^{T} {x}_{j} {∀}_{i , j} where {p}_{i} and {p}_{j} are fixed$$

$${X}_{: , i} = {x}_{i} {∀}_{i} where {p}_{i} is fixed \qquad ( 18 )$$

$$Z ≽ 0 \qquad ( 19 )$$

$$rank ( Z ) = m$$

The problem above is also decomposed into two sub-problems and solved iteratively, where the two new distance constraints (i.e., Eqs. (18) and (19)) are added to the first sub-problem.

### Non-Square Requirement

In the framework disclosed herein, each module is modeled as a circle based on prior knowledge that a module is expected to be like a square. But, in some cases, a module can be a rectangle. For example, the soft module in fixed-outline floorplanning is a rectangle that has fixed area but a flexible aspect ratio. In these cases, a circle is not a good approximation, and strict distance constraints Eq. (5) may even degrade the quality of the solution.

To address this issue, an adaptive distance constraint that is based on the maximum aspect ratio of the modules and the value of Aᵢⱼ is used. With reference to FIG. 3A, the shaded circle pᵢ has a radius rᵢ. Let k be the maximum aspect ratio of the module. The “forbidden zone” of pᵢ is approximated as

$$\frac{2 {r}_{i}}{k}$$

(the line in FIG. 3A), which represents the length of the segment that cannot be occupied by other modules. Because

$$\frac{2 {r}_{i}}{k} + β = 2 {r}_{i}$$

and the distance between two circle centers is rᵢ+rⱼ−β, the distance constraint can be written as:

$${D}_{ij} \geq {( {r}_{j} - {r}_{i} + \frac{2 {r}_{i}}{k} )}^{2} \qquad ( 20 )$$

When k=1 (i.e., the module is expected to be a square), Eq. (20) is equivalent to Eq. (6). When k>1 (e.g., k=3), the module has a forbidden segment with length at least

$$\frac{2 {r}_{i}}{3}$$

which mimics a rectangle with width

$$\frac{2 {r}_{i}}{3} ,$$

and height 2rᵢ.

To make

$$2 {r}_{i} \frac{2 {r}_{i}}{k} = {s}_{i} ,$$

rᵢ is set to

$$\sqrt{\frac{{ks}_{i}}{4}} .$$

When pᵢ is connected with multiple modules in [symbol] . Eq. (20) should be adjusted. Otherwise, the circle might be squashed by other modules, as shown in FIG. 3B. To keep the “forbidden zone” for multiple modules, k in Eq. (20) is replaced by:

$${k}_{ij} = \frac{{A}_{ij}}{{\sum }_{l = {𝒩}_{i}} {A}_{il}} ( k - 1 ) + 1 \qquad ( 21 )$$

where [symbol] ᵢ is the neighbors of i in [symbol] .

The intuition is, if two modules are closely connected (i.e., Aᵢⱼ is large), then pⱼ is “allowed” to be closer to pᵢ but is always upper bounded by kᵢⱼ<k. Furthermore, because Dᵢⱼ=Dⱼᵢ, the distance constraint can be formalized by:

$${D}_{ij} > max ( {( {r}_{j} - {r}_{i} + \frac{2 {r}_{i}}{{k}_{ij}} )}^{2} , {( {r}_{i} - {r}_{j} + \frac{2 {r}_{j}}{{k}_{ji}} )}^{2} ) \qquad ( 22 )$$

### Overall Framework

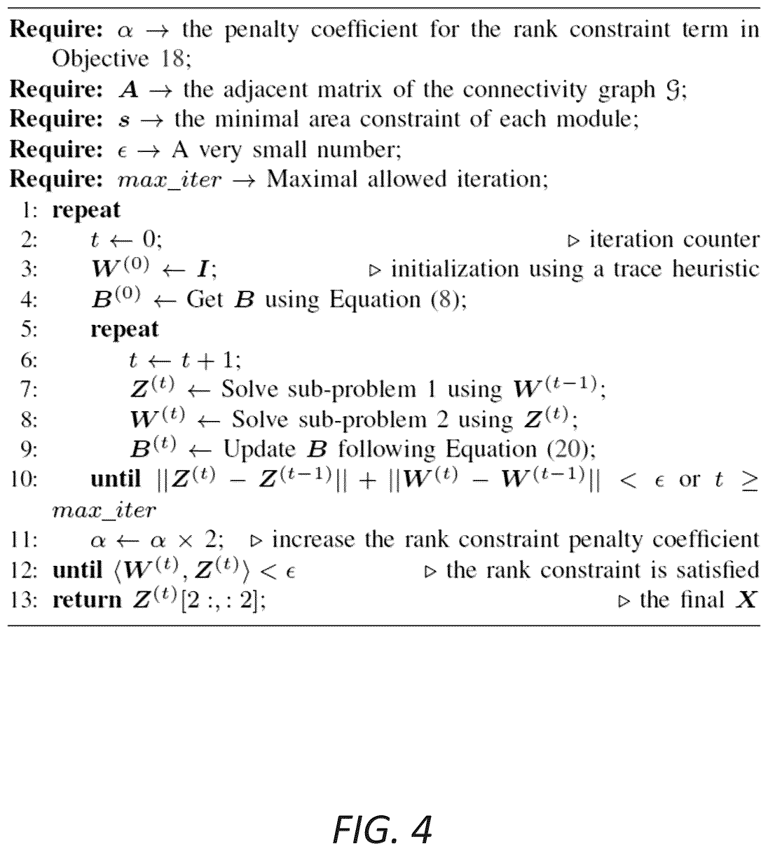

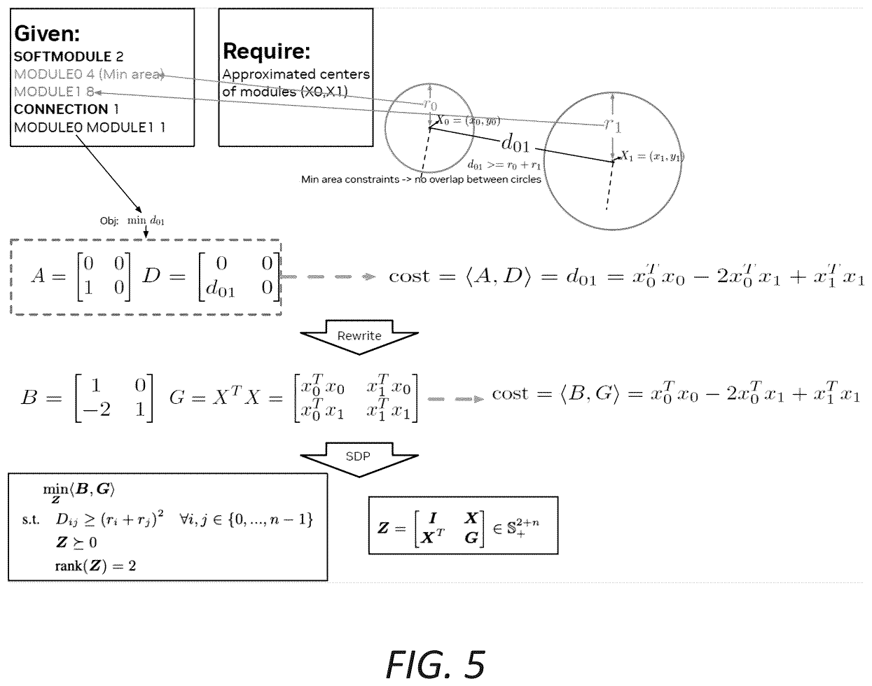

The overall framework combining the basic algorithm and the enhancing techniques is shown in pseudocode form in FIG. 4 and in workflow form in FIG. 5. Ideally, the smallest α that finds a feasible Z with rank 2 is used. To achieve this, start from a small α and increase it by a factor of 2 until the rank constraint is satisfied. For each α (lines 2-12), the two sub-problems are iteratively solved as previously described. Some of the enhancement techniques previously described are applied in this iterative process. For example, the constant matrix B is updated at each iteration (line 9) to estimate the Manhattan distance rather than a distance square. When the solution of the two sub-problems converge or an iteration limit is reached (line 10), the rank of Z is checked (line 12). If the rank is 2, the process is stopped, and the solution is returned. Otherwise, the rank constraint penalty, n is increased, and the process is repeated.

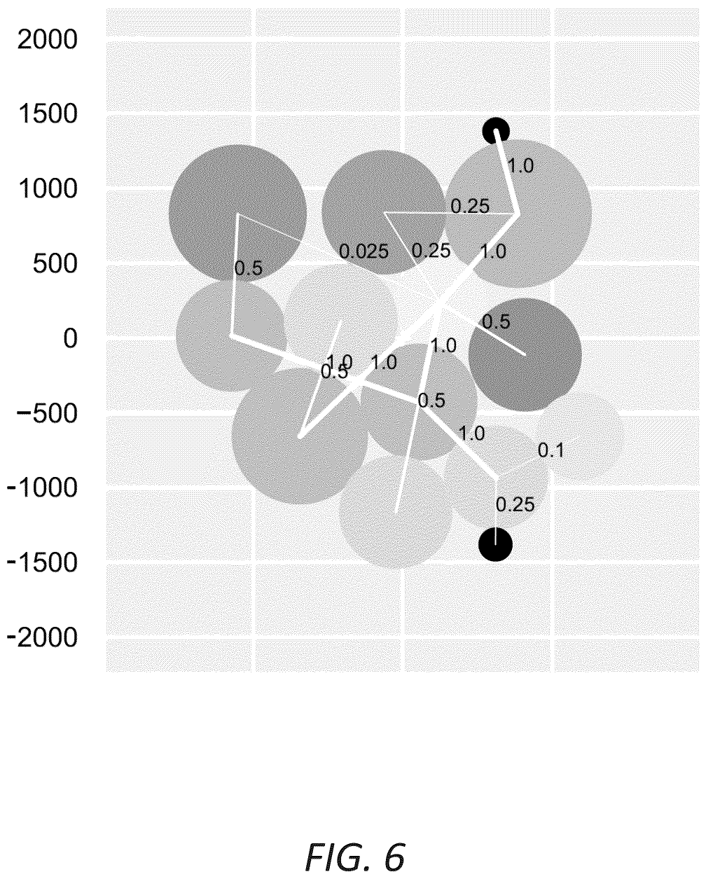

FIG. 6 is a diagram showing the final outcome of the method in graphical form. In this diagram, the areas of the circles are representative of the minimum area constraint of each module and the thickness of the lines between the circle is representative of the number of connections between the modules. The black circles represent boundary pins having a pre-placement constraint.

The disclosed framework, in one embodiment, may be implemented in Python. The convex optimization solver is MOSEK 10.0. For non-linear optimization, PyTorch Minimize with BFGS algorithm may be used.

A legalization framework may also be implemented: with the global floorplan as the input horizontal and vertical constraint graphs are constructed, then the shape optimization is modeled as a second order cone programming instance. Final HPWL is reported after the legalization.

As would be realized, global floorplanning is not limited to the automated fixed-outline floorplanning. A high-quality global floorplan with an accurate center coordinates approximation is helpful for manual floorplanning.

An SDP-based iterative framework that divides the problem into two convex sub-problems has been disclosed herein. Enhancement techniques to improve the flexibility, accuracy, and efficiency of the framework were also disclosed. Experimental results show that the proposed method achieves better performance than previous methods.

As would be realized by one of skill in the art, the methods described herein can be implemented on a system comprising a processor and memory, storing software that, when executed by the processor, implements the described methods.

As would further be realized by one of skill in the art, many variations on implementations discussed herein which fall within the scope of the invention are possible. Moreover, it is to be understood that the features of the various embodiments described herein were not mutually exclusive and can exist in various combinations and permutations, even if such combinations or permutations were not made express herein, without departing from the spirit and scope of the invention. Accordingly, the method disclosed herein is not to be taken as a limitation on the invention but as an illustration thereof. The scope of the invention is defined by the claims which follow.

1. A method for optimizing localization of a plurality of modules comprising:
receiving a list of modules, each module associated with a minimum area constraint;
receiving an adjacency matrix, where each entry in the adjacency matrix represents a weighted number of connections between a pair of the modules; and
iteratively localizing the modules to minimize a weighted wirelength of the connection between the modules.

2. The method of claim 1 wherein each module is modelled as a circle having a radius dependent on the associated minimum area constraint.

3. The method of claim 1 wherein the wirelength between modules is estimated by an inner product of the adjacency matrix and a distance matrix;
wherein the distance matrix contains the Euclidean distance square between each pair of modules.

4. The method of claim 1 wherein the minimization is a semidefinite programming problem that has been formulated as a convex iteration by replacement of a rank constraint of the semidefinite programming problem with an inner product between a target matrix and a direction matrix.

5. The method of claim 1 wherein the minimization is a semidefinite programming problem that has been formulated as a convex iteration by replacement of a rank constraint of the semidefinite programming problem with a nuclear norm convex relaxation.

6. The method of claim 4 wherein, at each iteration, the method comprises:
holding the direction matrix fixed;
optimizing the target matrix;
holding the optimized target matrix fixed; and
optimizing the direction matrix.

7. The method of claim 6 wherein the direction matrix is a matrix that makes the inner product of the direction matrix and the target matrix 0.

8. The method of claim 6 wherein the iteration terminates when the change in either the direction matrix or the target matrix is below a threshold.

9. The method of claim 6 wherein a coordinate matrix containing the optimized coordinates of the centers of the circles representing the modules is derived from the optimized target matrix.

10. The method of claim 6 wherein an adaptive cost is calculated during each iteration.

11. The method of claim 10 wherein the adaptive cost is based on a Manhattan distance between pairs of modules.

12. The method of claim 1 wherein one or more of the modules have connections to boundary pins having a fixed location.

13. The method of claim 4 wherein one or more of the modules have a fixed location.

14. The method of claim 11 wherein one or more distance constraints are added to the optimization iteration to address modules having a fixed location.

15. The method of claim 6 wherein one or more modules are assumed to have rectangular shapes.

16. The method of claim 13 wherein an adaptive distance metric based on a maximum aspect ratio of the rectangular modules is used.

17. The method of claim 13 wherein a forbidden zone is established that cannot be occupied by another module.

18. A system comprising:
a processor; and
software, executing on the processor, the software implementing the method of claim 6.
